(19) United States
(12) Patent Application Publication
(10) Pub. No.: US 2013/0189843 A1
(43) Pub. Date: Jul. 25, 2013

(54) SLURRY FOR PLANARIZING PHOTORESIST

(71) Applicants: You Wang, Cupertino, CA (US); Wen-Chiang Tu, Mountain View, CA (US); Lakshmanan Karuppiah, San Jose, CA (US); Yufei Chen, Cupertino, CA (US)

(72) Inventors: You Wang, Cupertino, CA (US); Wen-Chiang Tu, Mountain View, CA (US); Lakshmanan Karuppiah, San Jose, CA (US); Yufei Chen, Cupertino, CA (US)

(21) Appl. No.: 13/747,825

(22) Filed: Jan. 23, 2013

Related U.S. Application Data
(60) Provisional application No. 61/590,271, filed on Jan. 24, 2012.

(51) Int. Cl. H01L 21/306

(52) U.S. Cl. CPC H01L 21/30625
USPC 438/693; 252/79.1

(57) ABSTRACT

A slurry for planarization of a photoresist includes abrasive particles, an oxidizer, a surface activation chemical, and a solvent.

### CROSS-REFERENCE TO RELATED APPLICATIONS

This application claims priority to U.S. Provisional Application Ser. No. 61/590,271, filed Jan. 24, 2012, the entire disclosure of which is incorporated by reference.

### TECHNICAL FIELD

The present invention relates generally to chemical mechanical polishing of photoresist.

### BACKGROUND

In the process of fabricating modern semiconductor integrated circuits (IC), it is often necessary to planarize the outer surface of the substrate.

Chemical mechanical polishing (CMP) is one accepted method of planarization. This planarization method typically requires that a substrate be mounted on a carrier head. The exposed surface of the substrate is typically placed against a rotating polishing pad. The polishing pad can have a durable roughened surface. An abrasive polishing slurry is typically supplied to the surface of the polishing pad. The carrier head provides a controllable load on the substrate to push it against the polishing pad while the substrate and polishing pad undergo relative motion.

### SUMMARY

One step in the manufacture semiconductor integrated circuits (IC) and microelectromechanical (MEM) devices, is to deposit a layer of photoresist on a substrate. For some applications, e.g., FinFETs, it would be useful to planarize the photoresist. Unfortunately, planarization of photoresist appears to have been unsuccessful so far. For example, slurry compositions that are proposed for photoresist tend to either not remove the photoresist (e.g., the removal rate is zero or so low as to be commercially impractical), or result in delamination of the photoresist layer. Without being limited to any particular theory, one problem may be the softness of the photoresist and the low adhesion to the underlying substrate makes planarization more challenging. However, new slurry formulations, e.g., with proper selection of an oxidizer and/or surface activation chemical, may be able to provide satisfactory performance.

In one aspect, a slurry for planarization of a photoresist includes abrasive particles, an oxidizer, a surface activation chemical, and a solvent.

Implementations can include one or more of the following features. The abrasive particles may include alumina oxide or silicon dioxide. The abrasive particles may be 0.1-10 wt % of the slurry. The oxidizer may include ammonium peroxide or hydrogen peroxide. The oxidizer may be 0.5-10 wt % of the slurry. The oxidizer may be ammonium peroxide, and the oxidizer may be 2-4 wt % of the slurry. The oxidizer may be hydrogen peroxide, and the oxidizer may be 0.5-2 wt % of the slurry. The solvent may be water. The surface activation chemical may include glycine, carboxy acid or citric acid. The surface activation chemical may be 0.5-2 wt % of the slurry.

In another aspect, a method of polishing includes bringing a substrate having a photoresist layer disposed over a cobalt barrier layer into contact with a polishing pad, supplying a slurry described above to the polishing pad, and generating relative motion between the substrate and the polishing pad to planarize the photoresist layer.

Advantages may include optionally one or more of the following. A photoresist can be planarized at a commercially practical removal rate without delamination. Planarization can be performed without scratching of the substrate, thus avoiding defects. In conjunction with cleaning, the resulting substrate can have a low defect count. For example, the post barrier polishing defect count can be comparable to a silicon polishing process. The polishing rate can be tunable between about 100-8000 Å/min. Planarization efficiency can be in a range of 50%-90%.

### BRIEF DESCRIPTION OF DRAWINGS

FIGS. 1A-1C illustrate polishing of a substrate having a photoresist over an underlying layer.

### DETAILED DESCRIPTION

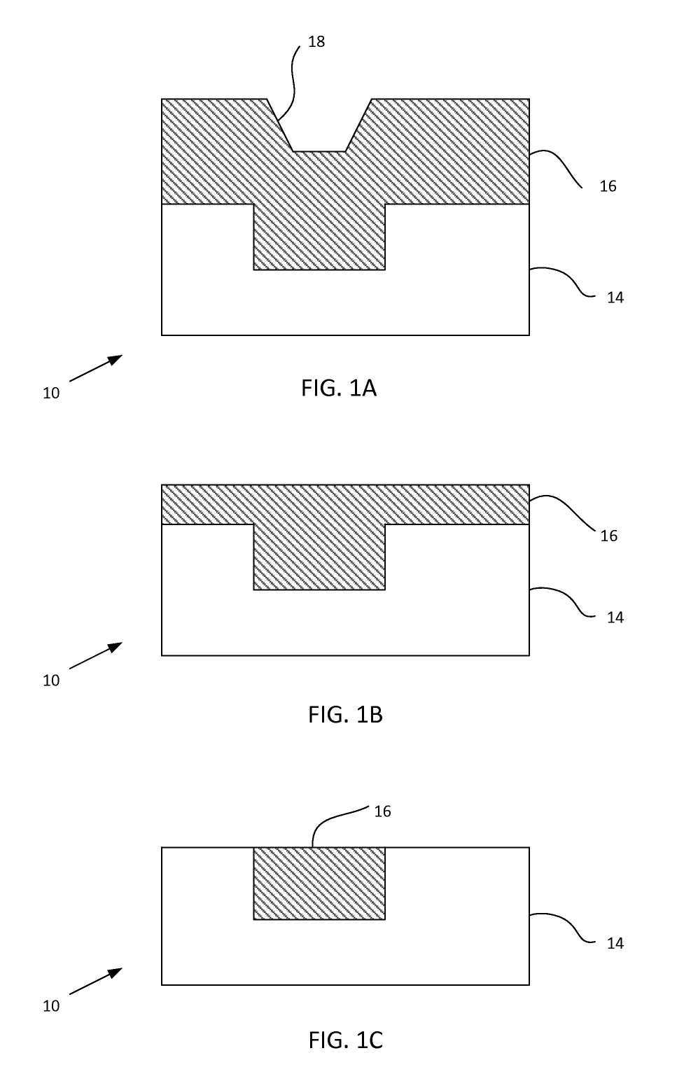

Referring to FIG. 1A, during an integrated circuit or microelectromechanical device fabrication, a substrate 10 can include a patterned layer 14 having a plurality of recesses or apertures in its upper surface, and a photoresist layer 16 disposed over the patterned layer 14. The patterned layer 14 can be an oxide, e.g. SiO₂. Typically there topology 18 on the outer surface of the photoresist layer 16 corresponding to the pattern in the underlying patterned layer 14. The substrate can include additional un-illustrated layers below the patterned layer 14, e.g., a glass or semiconductor wafer and/or conductive and/or dielectric layers formed between the wafer and the patterned layer 14.

Referring to FIG. 1B, following planarization, the photoresist layer 16 has a planar outer surface, but still covers the upper surface of the patterned layer 14. Referring to FIG. 1C, in some implementations, planarization continues until the upper surface of the patterned layer 14 is exposed.

As noted above, commercial slurries for polishing of photoresist do not give satisfactory performance.

A proposed slurry chemistry that might potentially address these problems can include (1) abrasive particles, (2) an oxidizer, (3) a surface activation chemical, and (4) a solvent such as water.

Typically, the range for the chemical components in the slurry is given below in Table 1.

TABLE 1

| | |
|---|---|
| Abrasive particles | 0.1-10 wt % |
| Oxidizer | 0.5-10 wt % |
| Surface activation chemical | 0.5-2 wt % |

The abrasive particles can be an oxide, such as fumed or colloidal aluminum oxide (Al₂O₃) or silica oxide (SiO₂). The size of the abrasive particles can be in a range of 20 nm-100 nm. For example, the abrasive particles can be, or can be similar to, those from B8755C or TSV-D1001 from Cabot.

The oxidizer can be ammonium persulfate (APS) and/or hydrogen peroxide. The oxidizer can be present in a concentration of 0.5-10 wt % of the slurry, e.g., 1-3 wt % of the slurry for hydrogen peroxide, or e.g., 1-5 wt % of the slurry for ammonium persulfate.

The surface activation chemical can be glycine, carboxy acid or citric acid.

Without being limited to any particular theory, the surface activation chemical can modify the hydrophobic surface of the photoresist. This can permit the oxidizer to interact with the chemistry of the photoresist. As a result, the surface can be weakened sufficiently to increase the polishing rate to commercially viable rates.

If necessary, the slurry can also include a pH adjustor to set the pH of the slurry, although this is optional. The pH adjustor can be KOH.

Polishing can be conducted at an applied pressure of 1-1.5 psi and at a platen rotation rate of 73-113 rpm.

### Example 1

Planarization of a layer of an Applied Material photoresist composition can be conducted, e.g., at a platen of a Mirra™ or Reflexion™ polishing system. Polishing can be performed using a soft microporous polyurethane pad, e.g., a Dura-soft or D200 polishing pad from Praxair. Polishing can be conducted at a pressure of 1.0 psi, and at a platen rotation rate of 73-113 rpm.

Slurry for the polishing can be provided by modifying a B8755C Cabot slurry by adding the following components:
ammonium persulfate (APS) 3 wt %

The resulting slurry can have a pH of 3-4; no pH adjustor is required.

Polishing with the Dura-soft pad at a platen rotation rate of 93 rpm resulted in a removal rate of 2000 Å/min without delamination and with acceptable post-cleaning defect count. Polishing with the D200 pad at a platen rotation rate of 93 rpm resulted in a removal rate of 1000 Å/min without delamination and with acceptable post-cleaning defect count. The polishing rate can be increased or decreased by increasing or decreasing, respectively, the platen rotation speed.

### Example 2

Planarization of a layer of an Applied Material photoresist composition can be conducted, e.g., at a platen of a Mirra™ or Reflexion™ polishing system. Polishing can be performed using a soft microporous polyurethane pad, e.g., a Fujibo polishing pad. Polishing can be conducted at a pressure of 1.0 psi, and at a platen rotation rate of 73-113 rpm.

Slurry for the polishing can be provided by modifying a TSV-D1001 Cabot slurry by adding the following components:
H₂O₂ 1 wt %

No pH adjustor is required.

Polishing with the Fujibo pad resulted in a removal rate of 1200 Å/min without delamination and with acceptable post-cleaning defect count.

1. A slurry for chemical mechanical planarization of a photoresist, comprising:
abrasive particles;
an oxidizer;
a surface activation chemical; and
a solvent.

2. The slurry of claim 1, wherein the abrasive particles comprise aluminum oxide or silicon dioxide.

3. The slurry of claim 2, wherein the abrasive particles are 0.1-10 wt % of the slurry.

4. The slurry of claim 1, wherein the oxidizer comprises ammonium persulfate or hydrogen peroxide.

5. The slurry of claim 4, wherein the oxidizer is 0.5-10 wt % of the slurry.

6. The slurry of claim 4, wherein the oxidizer comprises ammonium peroxide persulfate.

7. The slurry of claim 6, wherein the oxidizer is 2-4 wt % of the slurry.

8. The slurry of claim 4, wherein the oxidizer comprises hydrogen peroxide.

9. The slurry of claim 8, wherein the oxidizer is 0.5-2 wt % of the slurry.

10. The slurry of claim 1, wherein the solvent is water.

11. The slurry of claim 1, wherein the surface activation chemical comprises glycine, carboxy acid or citric acid.

12. The slurry of claim 11, wherein the surface activation chemical is 0.5-2 wt % of the slurry.

13. A method of polishing, comprising:
bringing a substrate having a photoresist layer into contact with a polishing pad;
supplying a slurry to the polishing pad, wherein the slurry includes abrasive particles, an oxidizer, a surface activation chemical, and a solvent; and
generating relative motion between the substrate and the polishing pad to planarize the photoresist layer.

14. The method of claim 13, wherein the abrasive particles comprise aluminum oxide or silicon dioxide.

15. The method of claim 14, wherein the abrasive particles are 0.1-10 wt % of the slurry.

16. The method of claim 13, wherein the oxidizer comprises ammonium persulfate or hydrogen peroxide.

17. The method of claim 16, wherein the oxidizer is 0.5-10 wt % of the slurry.

18. The method of claim 16 wherein the oxidizer comprises ammonium persulfate.

19. The method of claim 18, wherein the oxidizer is 2-4 wt % of the slurry.

20. The method of claim 16, wherein the oxidizer comprises hydrogen peroxide.

21. The method of claim 20, wherein the oxidizer is 0.5-2 wt % of the slurry.

22. The method of claim 21, wherein the solvent is water.

23. The method of claim 13, wherein the surface activation chemical comprises glycine, carboxy acid or citric acid.

24. The method of claim 11, wherein the surface activation chemical is 0.5-2 wt % of the slurry.
